(19) United States
(12) Patent Application Publication
(10) Pub. No.: US 2011/0097856 A1
(43) Pub. Date: Apr. 28, 2011

(54) METHOD OF MANUFACTURING WAFER LEVEL PACKAGE

(76) Inventors: Hong Won KIM, Gyunggi-do (KR); Joon Seok Kang, Gyunggi-do (KR); Doo Sung Jung, Gyunggi-do (KR); Seon Hee Moon, Seoul (KR)

(21) Appl. No.: 12/632,611

(22) Filed: Dec. 7, 2009

(30) Foreign Application Priority Data
Oct. 26, 2009 (KR) 10-2009-0101823

(51) Int. Cl. H01L 21/56

(52) U.S. Cl. 438/127; 257/E21.502

(57) ABSTRACT

Disclosed is a method of manufacturing a wafer level package, which includes arranging semiconductor dies on a carrier, forming a protective layer between the semiconductor dies of the carrier through screen printing, primarily heat hardening the protective layer, simultaneously pressing and secondarily heat hardening the protective layer, and removing the carrier, so that a thickness difference between the semiconductor dies and the protective layer is not formed and the warping of the wafer level package is reduced.

### CROSS REFERENCE TO RELATED APPLICATION

This application claims the benefit of Korean Patent Application No. 10-2009-0101823, filed Oct. 26, 2009, entitled “A Method Of Manufacturing A Wafer Level Package”, which is hereby incorporated by reference in its entirety into this application.

### BACKGROUND OF THE INVENTION

1. Technical Field

The present invention relates to a method of manufacturing a wafer level package.

2. Description of the Related Art Generally, tens or hundreds of chips are formed per wafer, but the chips alone cannot send and receive electrical signals using external electrical power, and are easily damaged by external impact because of having fine circuits. Accordingly, a packaging technique that enables the electrical connection of the chips and protects the chips from external impact has been more and more developed.

Alongside the recent advancement of the electronics industry is a gradually increasing demand for electronic components with increased functionality and small sizes. In particular, the current trend of the market which requires the fabrication of personal portable terminals which are lightweight, slim, short and small is being followed by the trend of reducing the thickness of a circuit board. Also, while a lot of work has continued to impart many functions on the limited area thereof, the development of a component-embedded substrate as part of next-generation multifunctional/small package technology is receiving attention.

Recently, thorough research into methods of manufacturing a wafer level package is being conducted, which include charging an encapsulation material into between semiconductor dies, that is, forming a protective layer for protecting the semiconductor dies, resulting in a reconstructed wafer.

However, in the case of a conventional wafer level package, because the protective layer between the semiconductor dies is hardened only by heat hardening, the protective layer may undergo hardening strain, undesirably causing the entire wafer level package to warp.

### SUMMARY OF THE INVENTION

Accordingly, the present invention has been made keeping in mind the problems encountered in the related art and the present invention is intended to provide a method of manufacturing a wafer level package, in which a protective layer is heat hardened so as to decrease its hardening strain, thus reducing the warping of the wafer level package.

An aspect of the present invention provides a wafer level package, including (A) arranging semiconductor dies on a carrier, (B) forming a protective layer between the semiconductor dies of the carrier through screen printing, (C) primarily heat hardening the protective layer, (D) simultaneously pressing and secondarily heat hardening the protective layer, and (E) removing the carrier.

In this aspect, a surface of the protective layer and a surface of the semiconductor dies may be brought to be flush with each other by (D).

In this aspect, the method may further include (F) subjecting either or both surfaces of the semiconductor dies to a redistribution layer process.

In this aspect, (A) may include (A1) providing a carrier having a release layer formed thereon and (A2) arranging the semiconductor dies on the release layer.

In this aspect, (B) may include (B1) forming screen printing masks on the semiconductor dies, (B2) filling spaces between the semiconductor dies with the protective layer through screen printing and (B3) removing the screen printing masks.

In this aspect, the protective layer may include an encapsulant or an epoxy molding compound.

In this aspect, a temperature of heat applied in (C) may be lower than a temperature of heat applied in (D).

In this aspect, a period of time required to apply heat in (C) may be shorter than a period of time required to apply heat in (D).

In this aspect, (C) may be maintained until the protective layer is solidified.

Another aspect of the present invention provides a method of manufacturing a wafer level package, including (A) arranging semiconductor dies on a carrier, (B) forming a protective layer between the semiconductor dies of the carrier through screen printing, (C) gradually heat hardening the protective layer while gradually pressing, and (D) removing the carrier.

In this aspect, a surface of the protective layer and a surface of the semiconductor dies may be brought to be flush with each other by (C).

In this aspect, the method may further include (E) subjecting either or both surfaces of the semiconductor dies to a redistribution layer process.

In this aspect, (A) may include (A1) providing a carrier having a release layer formed thereon and (A2) arranging the semiconductor dies on the release layer.

In this aspect, (B) may include (B1) forming screen printing masks on the semiconductor dies, (B2) filling spaces between the semiconductor dies with the protective layer through screen printing and (B3) removing the screen printing masks.

In this aspect, the protective layer may include an encapsulant or an epoxy molding compound.

### BRIEF DESCRIPTION OF THE DRAWINGS

The features and advantages of the present invention will be more clearly understood from the following detailed description taken in conjunction with the accompanying drawings, in which:

FIG. 1 is a flowchart showing a process of manufacturing a wafer level package according to a first embodiment of the present invention;

FIGS. 2 to 10 are cross-sectional views sequentially showing the process of manufacturing a wafer level package according to the first embodiment of the present invention;

FIG. 11 is a flowchart showing a process of manufacturing a wafer level package according to a second embodiment of the present invention; and

FIGS. 12 to 19 are cross-sectional views sequentially showing the process of manufacturing a wafer level package according to the second embodiment of the present invention.

### DESCRIPTION OF SPECIFIC EMBODIMENTS

Hereinafter, a detailed description will be given of embodiments of the present invention with reference to the accompanying drawings. Throughout the drawings, the same reference numerals refer to the same or similar elements, and redundant descriptions are omitted. In the description, in the case where known techniques pertaining to the present invention are regarded as unnecessary because they would make the characteristics of the invention unclear and also for the sake of description, the detailed descriptions thereof may be omitted.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

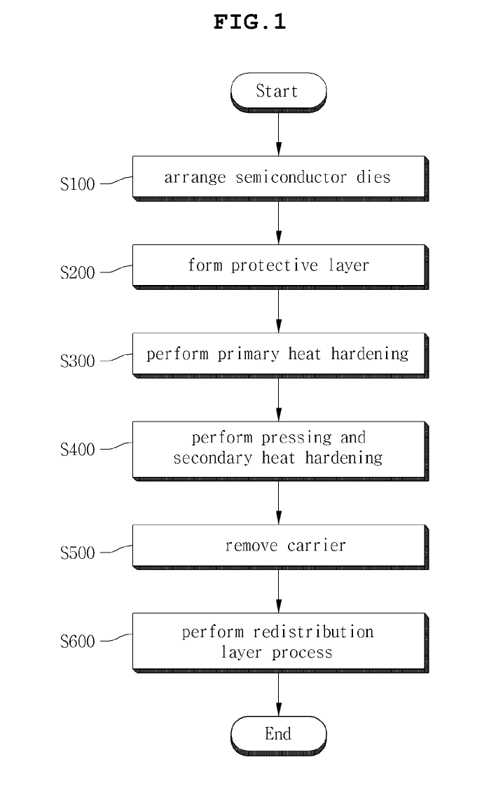

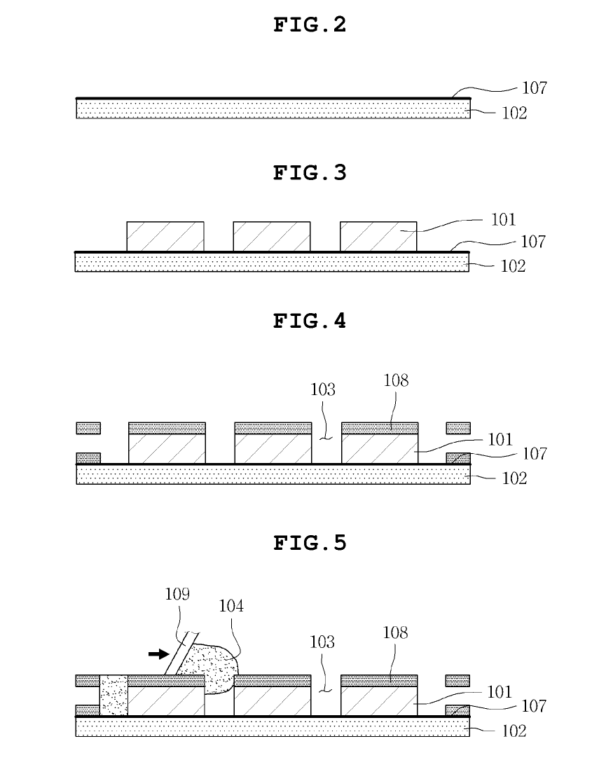

FIG. 1 is a flowchart showing a process of manufacturing a wafer level package according to a first embodiment of the present invention, and FIGS. 2 to 10 are cross-sectional views sequentially showing the process of manufacturing a wafer level package according to the first embodiment of the present invention. With reference to FIGS. 1 to 10, the method of manufacturing the wafer level package according to the first embodiment is described below.

As shown in FIG. 1, the method of manufacturing the wafer level package according to the present embodiment includes arranging semiconductor dies on a carrier (S100), forming a protective layer between the semiconductor dies of the carrier through a screen printing process (S200), primarily heat hardening the protective layer (S300), simultaneously pressing and secondarily heat hardening the protective layer (S400), removing the carrier (S500), and subjecting the semiconductor dies to a redistribution layer (RDL) process (S600).

Specifically, as shown in FIGS. 2 and 3, a release layer 107 is formed on a carrier 102, and semiconductor dies 101 are arranged on the release layer 107 (S100).

As such, the carrier 102 is a member functioning as a support for preventing the wafer level package from warping during the process of manufacturing the wafer level package, and has a thickness of for example about 100˜800 μm. Furthermore, the carrier 102 may be made of a material containing for example stainless steel or an organic material. In particular, in the case of stainless steel, it is advantageous because the wafer level package is easily separated therefrom.

The formation of the release layer 107 between the carrier 102 and the semiconductor dies 101 is desirable in terms of separating the carrier 102 in a subsequent procedure. The material of the release layer 107 may include one or more conductive metals selected from the group consisting of copper (Cu), gold (Au), silver (Ag), nickel (Ni), palladium (Pd) and platinum (Pt), or one or more insulating materials selected from the group consisting of polyimide, phenol, fluorine resin, PPO (Poly Phenylene Oxide) resin, glass fiber and paper. As such, the release layer 107 may be formed on the carrier 102 by for example thin film coating or sputtering.

The semiconductor dies 101, which are semiconductor chips formed on a wafer, indicate in the present embodiment good dies except for defective dies among the semiconductor dies formed on the wafer. Thus, when the present embodiment refers to “the arrangement of the semiconductor dies”, this is referring to the good dies arranged on the carrier.

When the semiconductor dies 101 are arranged on the release layer 107 formed on the carrier 102, spaces 103 between the semiconductor dies 101 may be formed. The spaces 103 are filled with a protective layer 104 in a subsequent procedure.

Next, as shown in FIGS. 4 to 6, screen printing masks 108 are formed on the semiconductor dies 101, and the spaces 103 between the semiconductor dies 101 are subjected to screen printing, thus forming the protective layer 104.

In the case where screen printing is carried out, the protective layer 104 is printed on the upper surface of the screen printing masks 108 using a squeegee 109, so that the protective layer 104 passes through the openings of the screen printing masks 108, thus forming the protective layer 104 in the spaces 103 between the semiconductor dies 101. Herein, the squeegee 109 may be formed by fixing an elastic material such as polyurethane gum to a jig made of wood or metal.

The protective layer 104 is responsible for fixing the semiconductor dies 101 and insulating the semiconductor dies 101 from each other, as an encapsulation material. As such, the protective layer 104 may be made of an encapsulant or an epoxy molding compound (EMC).

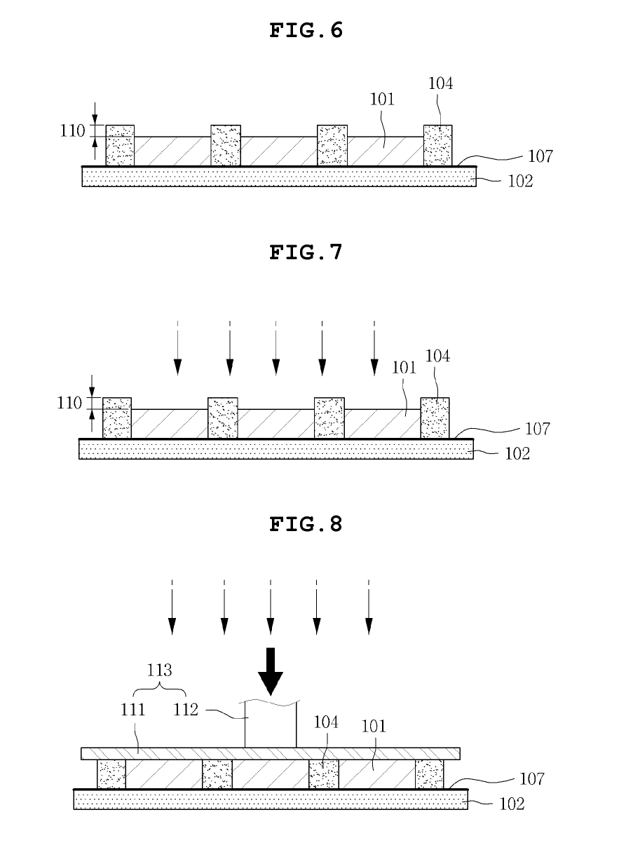

After filling the spaces 103 between the semiconductor dies 101 with the protective layer 104, the screen printing masks 108 are removed from the semiconductor dies 101. As such, as shown in FIG. 6, a thickness difference 110 between the protective layer 104 and the semiconductor dies 101 may be formed corresponding to the thickness of the screen printing masks 108. Such a thickness difference 110 makes it difficult to perform a subsequent build-up process on the semiconductor dies 101.

Next, as shown in FIG. 7, the protective layer 104 formed in the spaces 103 is primarily heat hardened (S300).

As such, primary heat hardening is performed such that the protective layer 104 is not hardened to become hard but is pre-baked and thus solidified. This solidification indicates that the protective layer 104 is not hardened to the state of a firm solid but its viscosity is increased to maintain the shape of the protective layer 104, so that the protective layer is put in an intermediate flexible phase between a solid and a liquid.

Because primary heat hardening does not completely harden the protective layer 104, lower temperature heat may be applied or the period of time in which heat is applied may be shorter, compared to secondary heat hardening.

Next, as shown in FIG. 8, while the protective layer 104 formed in the spaces 103 is pressed, it is secondarily heat hardened (S400).

For example, the protective layer 104 may be pressed by a pressing member 113 equipped with a flat pressing plate 111 and a pressing rod 112 at the center of the pressing plate 111. Because the protective layer 104 is solidified by the primary heat hardening, even when it is pressed using the pressing member 113, it does not spread to the extent to which it greatly deviates from its original shape like a liquid material. Furthermore, the protective layer is not completely hardened upon primary heat hardening, and thus the surface of the semiconductor dies 101 and the surface of the protective layer 104 are brought to be flush with each other by pressing. Hence, the thickness difference 110 between the protective layer 104 and the semiconductor dies 101 may be eliminated.

Furthermore, when the protective layer 104 is pressed, hardening strain of the protective layer occurring upon heat hardening may be decreased, thus reducing warping of the wafer level package.

Because in secondary heat hardening the protective layer 104 is completely hardened and turned into a firm solid, higher temperature heat may be applied or the period of time in which heat is applied may be increased, compared to primary heat hardening.

Although the pressing member 113 is illustrated to apply pressure in FIG. 8, air pressure or hydraulic pressure may be used, and any means may be used as long as the upper surface of the semiconductor dies 101 and the upper surface of the protective layer 104 are brought to be flush with each other.

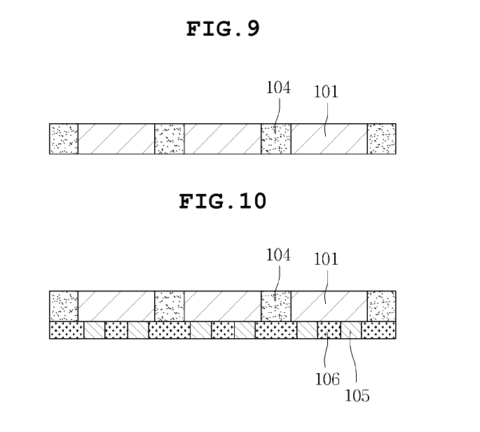

Next, as shown in FIG. 9, the carrier 102 is removed from the semiconductor dies 101 and the protective layer 104 (S500).

In the case where the release layer 107 is formed on the carrier 102, it is easy to separate the carrier 102 from the semiconductor dies 101 and the protective layer 104.

Next, as shown in FIG. 10, the semiconductor dies 101 are subjected to an RDL process (S600).

Specifically, the semiconductor dies 101 include, at one surface thereof, a wiring layer 105 formed to be electrically connected to the semiconductor dies 101 and a passivation layer 106 formed to protect the semiconductor dies 101 from the outside. As such, in order to connect the semiconductor dies 101 to an external device (not shown) and a PCB (not shown) by means of the wiring layer 105, openings are formed in the passivation layer 106 corresponding to portions where the wiring layer 105 is formed, thus exposing the wiring layer 105 to the outside. The wiring layer 105 may be made of an electrically conductive metal such as gold, silver, copper, nickel, etc.

Although the formation of the passivation layer 106 and the wiring layer 105 only on the lower surface of the semiconductor dies 101 and the protective layer 104 is illustrated in FIG. 10, the present invention is not limited thereto. Because the upper surface of the wafer level package according to the present embodiment is also flattened by pressing, it is possible to form a passivation layer 106 and a wiring layer 105 on the upper surface of the semiconductor dies 101 and the protective layer 104. Further, the wiring layer 105 and the passivation layer 106 may be provided in the form of a multilayer by a build-up process.

The wafer level package according to the first embodiment as shown in FIG. 10 is manufactured by the above manufacturing process.

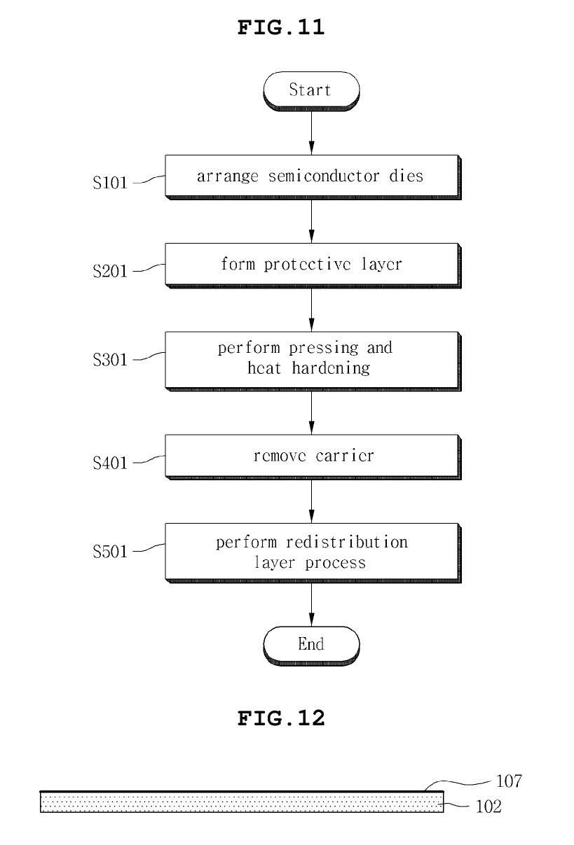

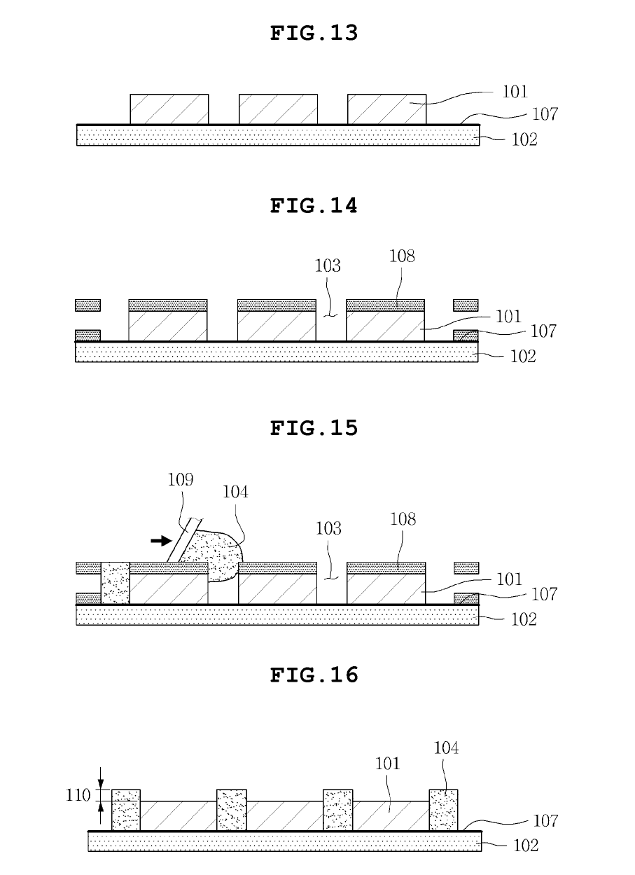

FIG. 11 is a flowchart showing a process of manufacturing a wafer level package according to a second embodiment of the present invention, and FIGS. 12 to 19 are cross-sectional views sequentially showing the process of manufacturing a wafer level package according to the second embodiment of the present invention. With reference to FIGS. 11 to 19, the method of manufacturing the wafer level package according to the present embodiment is described below. Herein, the same or similar elements are designated by the same reference numerals, and the description that overlaps the description according to the first embodiment is omitted.

As shown in FIG. 11, the method of manufacturing the wafer level package according to the present embodiment includes arranging semiconductor dies on a carrier (S101), forming a protective layer between the semiconductor dies of the carrier through screen printing (S201), gradually heat hardening the protective layer while gradually pressing it (S301), removing the carrier (S401), and subjecting the semiconductor dies to an RDL process (S501).

Specifically, as shown in FIGS. 12 to 16, semiconductor dies 101 are arranged on a carrier 102 having a release layer 107 formed thereon (S101), and spaces 103 between the semiconductor dies 101 are filled with a protective layer 104 through screen printing (S201).

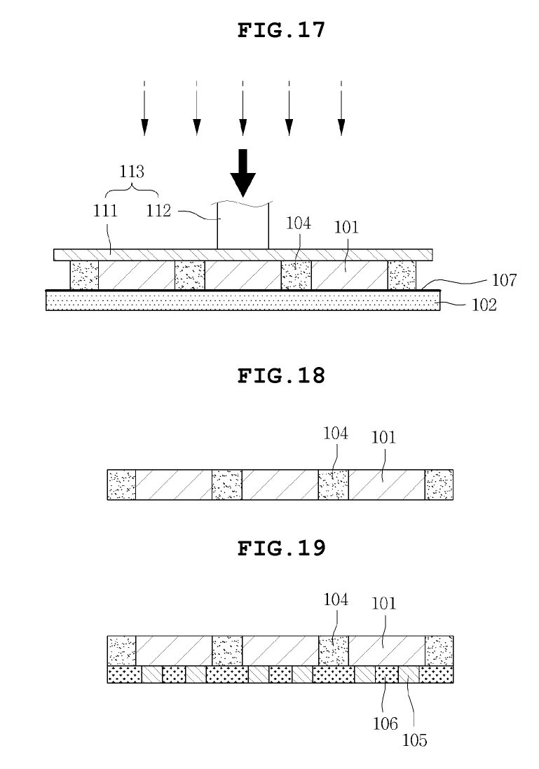

Next, as shown in FIG. 17, the protective layer 104 is gradually heat hardened while being gradually pressed (S301).

Specifically, low pressure and heat are first applied to the protective layer 104 so that the protective layer 104 is gradually solidified, and then pressure and heat are increased more and more, thus hardening the protective layer 104 and bringing the upper surface of the protective layer 104 and the upper surface of the semiconductor dies 101 to be flush with each other. Accordingly, a thickness difference 110 between the protective layer 104 and the upper semiconductor dies 101 as shown in FIG. 16 is eliminated. In the case where high pressure is applied before the protective layer 104 is solidified, the protective layer 104 may be spread and be greatly deviated from its original shape. So, it is desirable to apply a low pressure until the protective layer 104 has solidified.

Next, as shown in FIGS. 18 and 19, the carrier 102 is removed (S401), and the semiconductor dies 101 are subjected to an RDL process (S501).

The wafer level package according to the second embodiment as shown in FIG. 19 is manufactured by the above manufacturing process.

As described hereinbefore, the present invention provides a method of manufacturing a wafer level package. According to the present invention, because a protective layer is heat hardened while being pressed, hardening strain of the protective layer is decreased, and thus warping of the wafer level package is also reduced.

Also, according to the present invention, because the protective layer is heat hardened while being pressed, a thickness difference between the semiconductor dies and the protective layer is not formed, thus making it easy to perform subsequent procedures.

Also, according to the present invention, because the protective layer is first solidified by primary heat hardening, even when it is pressed upon secondary heat hardening, the protective layer does not spread to the extent to which it greatly deviates from its original shape.

Also, according to the present invention, a release layer is formed between the carrier and the semiconductor dies, thus facilitating the separation of the carrier from the wafer level package.

Although the embodiments of the present invention regarding the method of manufacturing the wafer level package have been disclosed for illustrative purposes, those skilled in the art will appreciate that a variety of different modifications, additions and substitutions are possible, without departing from the scope and spirit of the invention as disclosed in the accompanying claims. Accordingly, such modifications, additions and substitutions should also be understood as falling within the scope of the present invention.

1. A method of manufacturing a wafer level package, comprising:
(A) arranging semiconductor dies on a carrier;
(B) forming a protective layer between the semiconductor dies of the carrier through screen printing;
(C) primarily heat hardening the protective layer;
(D) simultaneously pressing and secondarily heat hardening the protective layer; and
(E) removing the carrier.

2. The method as set forth in claim 1, wherein a surface of the protective layer and a surface of the semiconductor dies are brought to be flush with each other by (D).

3. The method as set forth in claim 1, further comprising (F) subjecting either or both surfaces of the semiconductor dies to a redistribution layer process.

4. The method as set forth in claim 1, wherein (A) comprises:
(A1) providing a carrier having a release layer formed thereon; and
(A2) arranging the semiconductor dies on the release layer.

5. The method as set forth in claim 1, wherein (B) comprises:
(B1) forming screen printing masks on the semiconductor dies;
(B2) filling spaces between the semiconductor dies with the protective layer through screen printing; and
(B3) removing the screen printing masks.

6. The method as set forth in claim 1, wherein the protective layer comprises an encapsulant or an epoxy molding compound.

7. The method as set forth in claim 1, wherein a temperature of heat applied in (C) is lower than a temperature of heat applied in (D).

8. The method as set forth in claim 1, wherein a period of time required to apply heat in (C) is shorter than a period of time required to apply heat in (D).

9. The method as set forth in claim 1, wherein (C) is maintained until the protective layer is solidified.

10. A method of manufacturing a wafer level package, comprising:
(A) arranging semiconductor dies on a carrier;
(B) forming a protective layer between the semiconductor dies of the carrier through screen printing;
(C) gradually heat hardening the protective layer while gradually pressing; and
(D) removing the carrier.

11. The method as set forth in claim 10, wherein a surface of the protective layer and a surface of the semiconductor dies are brought to be flush with each other by (C).

12. The method as set forth in claim 10, further comprising (E) subjecting either or both surfaces of the semiconductor dies to a redistribution layer process.

13. The method as set forth in claim 10, wherein (A) comprises:
(A1) providing a carrier having a release layer formed thereon; and
(A2) arranging the semiconductor dies on the release layer.

14. The method as set forth in claim 10, wherein (B) comprises:
(B1) forming screen printing masks on the semiconductor dies;
(B2) filling spaces between the semiconductor dies with the protective layer through screen printing; and
(B3) removing the screen printing masks.

15. The method as set forth in claim 10, wherein the protective layer comprises an encapsulant or an epoxy molding compound.

16. A method of manufacturing a wafer level package, comprising:
(A) arranging semiconductor dies on a carrier;
(B) forming a protective layer between the semiconductor dies of the carrier through screen printing;
(C) heat hardening the protective layer while pressing; and
(D) removing the carrier.

17. The method as set forth in claim 16, wherein (C) comprises:
(C1) primarily heat hardening the protective layer; and
(C2) simultaneously pressing and secondarily heat hardening the protective layer.

18. The method as set forth in claim 16, wherein the step (C) is performed by gradually heat hardening the protective layer while gradually pressing.
